(19) United States
(12) Patent Application Publication
(10) Pub. No.: US 2024/0404929 A1
(43) Pub. Date: Dec. 5, 2024

(54) ELECTRONIC DEVICE WITH WAFER LEVEL CAPACITOR

(71) Applicant: TEXAS INSTRUMENTS INCORPORATED, DALLAS, TX (US)

(72) Inventors: Kapil Sahasrabudhe, ALLEN, TX (US); Kyoung Min Lee, CARY, NC (US); Philomena Brady, FARMERS BRANCH, TX (US)

(21) Appl. No.: 18/325,708

(22) Filed: May 30, 2023

(51) Int. Cl. H01L 23/495; H01L 23/00

(52) U.S. Cl. CPC H01L 23/49589; H01L 23/49513; H01L 24/27; H01L 24/29; H01L 24/32; H01L 24/48; H01L 24/73; H01L 24/83; H01L 24/85; H01L 24/92; H01L 23/3107; H01L 2224/27416; H01L 2224/27436; H01L 2224/29082; H01L 2224/32245; H01L 2224/48091; H01L 2224/48105; H01L 2224/48245; H01L 2224/48257; H01L 2224/48463; H01L 2224/73265; H01L 2224/83191; H01L 2224/85207; H01L 2224/92247

(57) ABSTRACT

An electronic device includes a leadframe having a die pad and leads. A die having an active side is attached to the die pad. The die further includes a dielectric layer deposited on a side of the die opposite that of the active side and an die attach film deposited on the dielectric layer. Wire bonds are attached from the active side of the die to the leads. A critical signal wire bond is attached from the active side of the die to the die pad. A mold compound encapsulates the die, the wire bonds, the critical signal wire bond, and a portion of the leadframe. A stacked formation of the die, the dielectric layer, and the die attach film form a capacitor that filters noise from a critical signal carried by the critical signal wire bond.

### TECHNICAL FIELD

The present disclosure relates to an electronic device and more specifically, to an integrated circuit package having a package level capacitor.

### BACKGROUND

Analog and digital integrated circuits (IC) utilize on-chip capacitors (metal to metal; poly silicon caps, etc.) to serve multiple purposes, including noise filtering, charge storage, etc. These on-chip capacitors require substantial space on the IC chip, which increases the chip size and the overall size of the IC package. The increase in size further increases material and fabrication costs. In addition, during fabrication, particles from the capacitors can become embedded in the die and create short circuits in the die and other components on the die thereby compromising the signal integrity of the IC.

### SUMMARY

In described examples, an electronic device includes a leadframe having a die pad and leads. A die having an active side is attached to the die pad. The die further includes a dielectric layer deposited on a side of the die opposite that of the active side and an die attach film deposited on the dielectric layer. Wire bonds are attached from the active side of the die to the leads. A critical signal wire bond is attached from the active side of the die to the die pad. A mold compound encapsulates the die, the wire bonds, the critical signal wire bond, and a portion of the leadframe. A stacked formation of the die, the dielectric layer, and the die attach film form a capacitor that filters noise from a critical signal connected by the critical signal wire bond.

In still another described example, a method includes providing a die, where the die has an active side and a non-active side opposite that of the active side. A die attach film is attached on the non-active side of the die and the non-active side of the die is attached to a die pad of a leadframe. Wire bonds are attached from the active side of the die to leads of the leadframe. A critical signal wire bond is attached from the active side of the die to the die pad and a molding compound is formed over the die, the wire bonds, the critical signal wire bond, and a portion of the leadframe. The formation of the die and the die attach film form a capacitor that filters noise from a critical signal from the die to the die pad via the critical signal wire bond.

In still another described example, an electronic device includes a leadframe having a die pad and leads. A die is attached to the die pad, where the die includes an active side and a non-active side opposite that of the active side. A die attach film is attached to the non-active side of the die that facilitates attachment of the die to the die pad. Wire bonds are attached from the active side of the die to the leads. In addition, a critical signal wire bond is attached from the active side of the die to the die pad. A mold compound encapsulates the die, the critical signal wire bond, and a portion of the leadframe. A stacked formation of the die and the die attach film form a capacitor that filters noise from a critical signal carried by the critical signal wire bond.

### BRIEF DESCRIPTION OF THE DRAWINGS

FIG. 1A illustrates a perspective view of an example electronic device.

FIG. 1A illustrates a cross-sectional view of the example electronic device of FIG. 1A.

FIG. 2A illustrates a perspective view of another example electronic device.

FIG. 2B illustrates a cross-sectional view of the example electronic device of FIG. 2A.

FIG. 3A is a top view of a wafer including multiple dies, in an example.

FIG. 3B illustrates a cross-sectional view of a die in the early stages of fabrication, in an example.

FIG. 3C illustrates a cross-sectional view of the die of FIG. 3B after the deposition of a dielectric, in an example.

FIG. 3D illustrates a cross-sectional view of the die of FIG. 3C after undergoing attachment of a die attach film to the dielectric layer, in an example.

FIG. 3E illustrates a cross-sectional view of an electronic device in the early stages of assembly, in an example.

FIG. 3F illustrates a cross-sectional view after attachment of the die of FIG. 3D to a leadframe of the electronic device of FIG. 3E, in an example.

FIG. 3G illustrates a cross-sectional view of the electronic device of FIG. 3F after attachment of wire bonds to the leadframe, in an example.

FIG. 3H illustrates a cross-sectional view of the electronic device of FIG. 3G after the formation of a molding compound, in an example.

### DETAILED DESCRIPTION

Analog and digital integrated circuits (IC) utilize on-chip capacitors (metal to metal; poly silicon caps, etc.) to serve multiple purposes, including noise filtering, charge storage, etc. These on-chip capacitors require substantial space on the IC chip, which increases the chip size and the overall size of the IC package. The increase in size further increases material and fabrication costs.

Disclosed herein is an electronic device that implements a package level capacitor to replace one or more on-chip capacitors, where the one or more on-chip capacitors are configured to, for example, filter noise, ripples, overshoot ringing, or changes from critical signals (e.g., reference voltage, output signal, etc.) from the chip or die. The package level capacitor is arranged between the die and a die pad of a leadframe. The package level capacitor includes an electrically grounded substrate of the die as one conductive plate of the capacitor and an electrically conductive die attach film along with the die pad as another conductive plate of the capacitor. A dielectric (e.g., oxide) is disposed between the substrate of the die and the die attach film to thereby form the package level capacitor. A wire bond is provided to connect a critical signal from the die to the die pad. Thus, the package level capacitor can be used for similar functions as the on-chip capacitors thereby eliminating one or more on-chip capacitors. Elimination of one or more on-chip capacitors reduces the size of the chip or die, which in turn reduces the overall size and therefore costs of the electronic device. In addition, the reduced size of the die results in more dies per wafer. As a result, less wafers are required to fabricate the same number of dies thereby relieving supply constraints and reducing material costs.

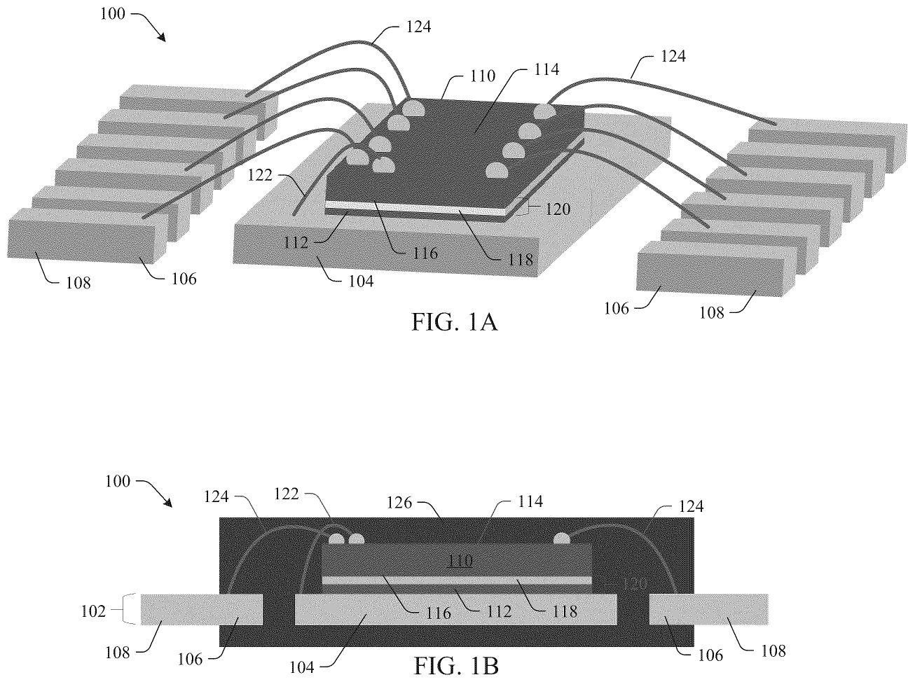

FIG. 1A is a perspective view of an example electronic device (e.g., integrated circuit (IC) package) 100 and FIG. 1B is a cross-sectional view of the electronic device 100. The electronic device 100 can be comprised of leaded or non-leaded integrated circuit packages. Some example IC packages can include a small outline package (SOP), a single in-line package (SIP), a double in-line package (DIP), a quad flat no-lead (QFN) package, a quad flat package (QFP), ball-grid array (BGA), etc. The electronic device 100 includes a leadframe (e.g., copper) 102 comprising a die pad 104 and leads comprised of inner leads 106 and outer leads 108. A die 110 is attached to the die pad 104 of the leadframe 102 via an electrically conductive die attach film 112.

The die 110 includes an active side 114 and a non-active side 116 opposite that of the active side 114. The non-active side 116 is comprised of an electrically grounded and conductive substrate (e.g., silicon, gallium nitride, silicon carbide). A dielectric layer (e.g., oxide layer) 118 is deposited on the substrate (non-active side) 116 of the die 110. The electrically conductive die attach film 112 is formed over the dielectric layer 118 and is directly connected to the electrically conductive die pad (e.g., copper die pad) 104. The electrically grounded and conductive substrate 116 of the die 110 forms one conductive plate of a package level capacitor (capacitor) 120. The die attach film 112 is an electrically conductive film that along with the die pad 104 forms the other plate of the capacitor 120. A thickness of the die attach film 112 is, for example, approximately 20-25 microns. Thus, the dielectric layer 118 is disposed between the substrate 116 and the die attach film 112 thereby forming the capacitor 120. A thickness of the dielectric layer 118 is approximately 3000-5000 A, but can be changed (e.g., thicker or thinner) to obtain a specific capacitance value.

A critical signal wire bond 122 is attached from the active side 114 of the die 110 to the die pad 104. The critical signal wire bond 122 is connected to a critical signal (e.g., reference voltage, output signal, etc.) on the die 110 and therefore connects the critical signal to the capacitor 120. Critical signals in IC packages may need to be at specific levels (e.g., voltage level) so as not to compromise the operation of the IC package. The formation of the capacitor 120 between the die 110 and the die pad 104 of the leadframe 102 enables the capacitor 120 to filter, for example, noise, ripples, overshoot ringing, or changes in the critical signal just as the on-chip capacitors, thereby stabilizing the critical signal.

Additional wire bonds 124 provide a connection from the active side 114 of the die 110 to the inner leads 106 of the leadframe 102. A mold compound 126 (shown only in FIG. 1B) is formed over and encapsulates the die 110, the critical signal wire bond 122, the wire bonds 124, the die pad 104 and the inner leads 106. In a non-leaded IC package (e.g., QFN), the mold compound 126 covers all but one surface of the leadframe 102, where the one surface not covered faces away from the die 110 and the electronic device 100.

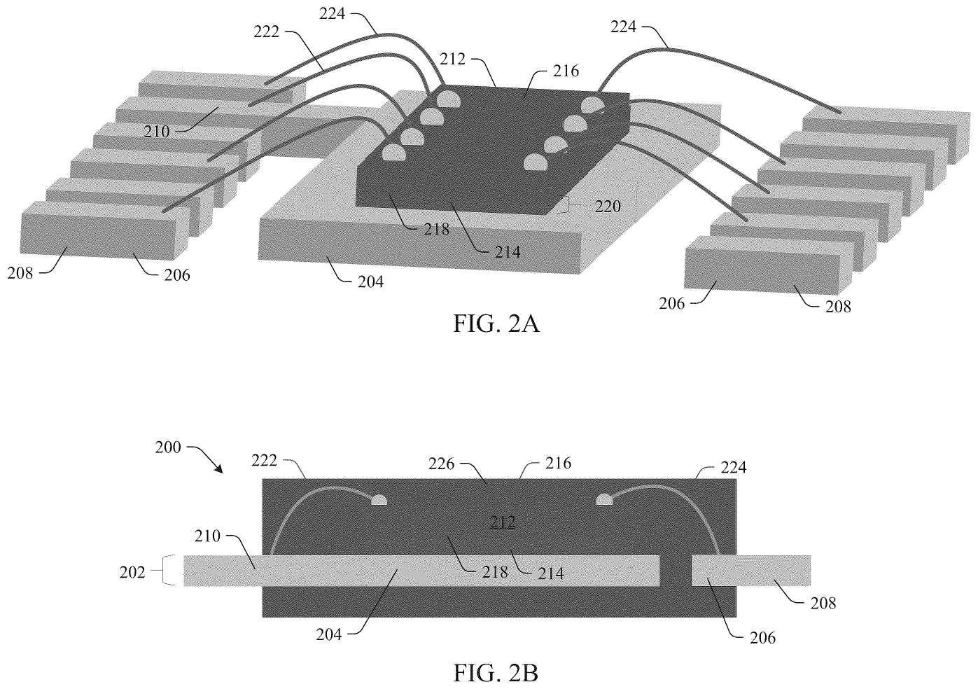

FIG. 2A is a perspective view of another example electronic device (e.g., integrated circuit (IC) package) 200 and FIG. 2B is a cross-sectional view of the electronic device 200. The electronic device 200 can be comprised of leaded or non-leaded integrated circuit packages. Some example IC packages can include a small outline package (SOP), a single in-line package (SIP), a double in-line package (DIP), a quad flat no-lead (QFN) package, a quad flat package (QFP), etc. The electronic device 200 includes a leadframe 202 comprising a die pad 204 and leads comprised of inner leads 206 and outer leads 208. In addition, the leadframe 202 further includes a fused lead 210 that is fused to the die pad 204. A die 212 is attached to the die pad 204 of the leadframe 202 via a die attach film 214.

The die 212 includes an active side 216 and a non-active side comprised of an electrically conductive substrate (e.g., silicon, gallium nitride, silicon carbide) 218 opposite that of the active side 216. The die attach film 214 is formed over the substrate 218 of the die 212. The electrically conductive substrate 218 of the die 212 forms one conductive plate of a package level capacitor (capacitor) 220. The die pad 204 forms the other conductive plate of the capacitor 220. The die attach film 214 is disposed between the substrate 218 and the die pad 204 and forms the dielectric layer of the capacitor 220. The thickness of the die attach film 214 is, for example, approximately 20-25 um.

A critical signal wire bond 222 is attached from the active side 216 of the die 212 to the fused lead 210. The critical signal wire bond 222 is connected to a critical signal (e.g., reference voltage, output signal, etc.) on the die 212 and connects the critical signal to the fused lead 210 and therefore to the package level capacitor 220. The formation of the capacitor 220 between the die 212 and the die pad 204 of the leadframe 202 enables the capacitor 220 to filter, for example, noise, ripples, overshoot ringing, or changes in the critical signal just as the on-chip capacitors, thereby stabilizing the critical signal.

Additional wire bonds 224 provide a connection from the active side 216 of the die 212 to the inner leads 206 of the leadframe 202. A mold compound 226 (shown only in FIG. 2B) is formed over and encapsulates the die 212, the critical signal wire bond 222, the wire bonds 224, the die pad 204 and the inner leads 206. In a non-leaded IC package (e.g., QFN), the mold compound 226 covers all but one surface of the leadframe 202, where the one surface not covered faces away from the die 212 and the electronic device 200.

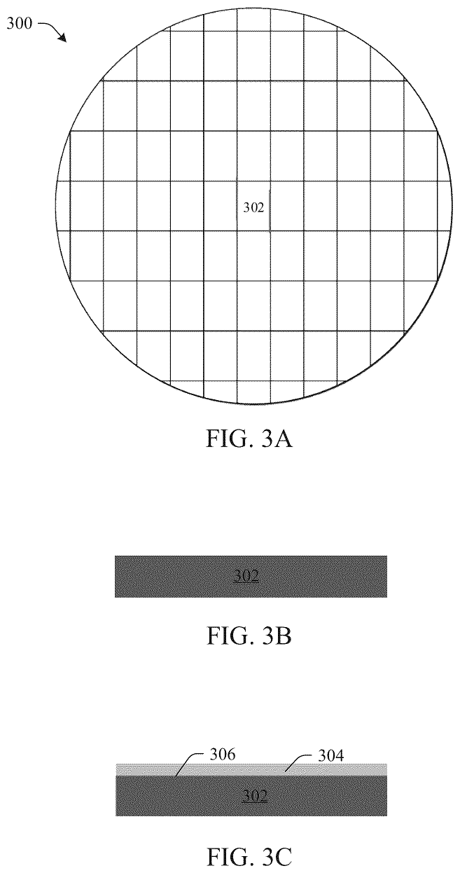

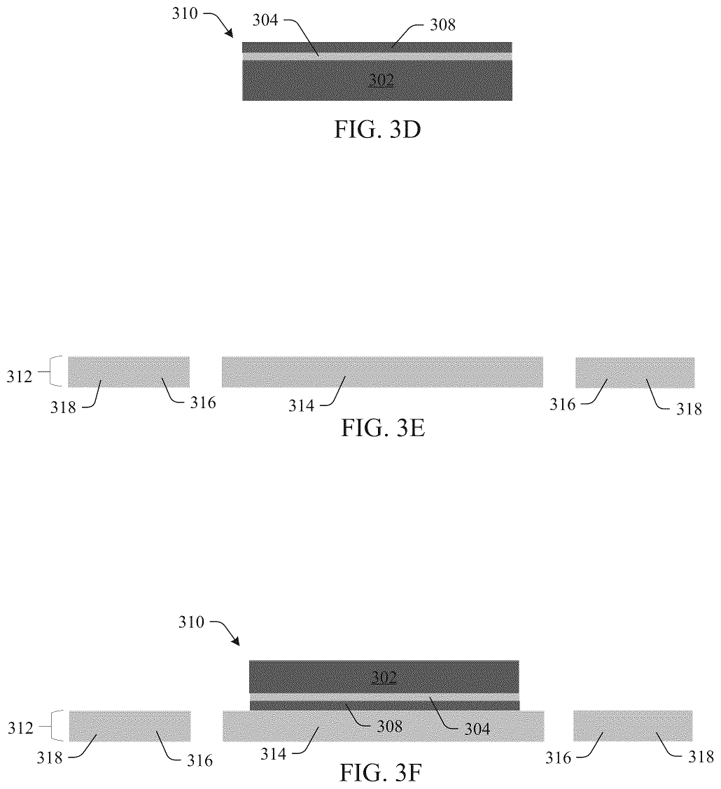

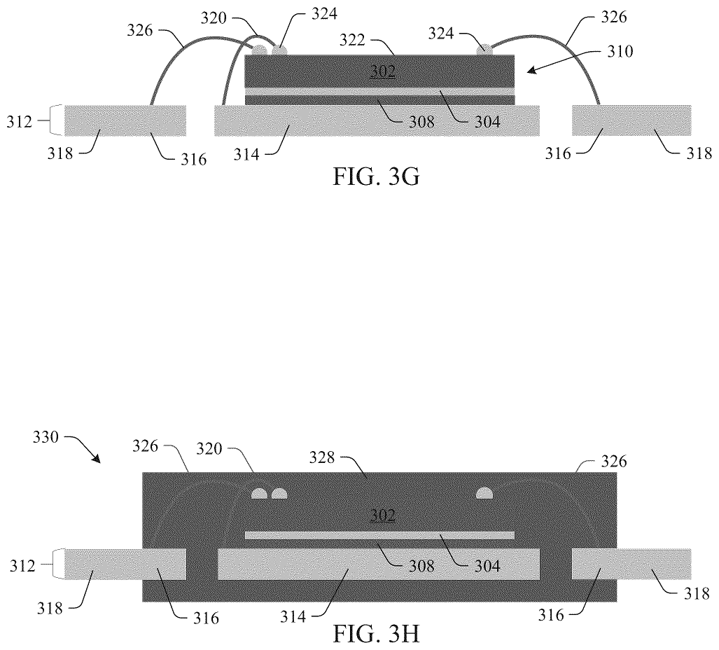

FIGS. 3A-3D illustrate a fabrication process associated with the formation of the dies for the electronic device 100 illustrated in FIGS. 1A and 1B. FIGS. 3E-3H illustrate an assembly process associated with the electronic device in FIGS. 1A and 1B. Specifically, Referring to FIG. 3A, FIG. 3A is a schematic diagram of a wafer 300, in accordance with various examples. For example, the wafer 300 may be a silicon wafer. The wafer 300 comprises multiple dies 302. The manufacturing techniques described below may be performed on individual dies 302 (post-singulation), or the techniques may be more efficiently performed on a mass scale, e.g., simultaneously on multiple dies 302 of the wafer 300 (pre-singulation). For convenience and clarity, the remaining drawings show one die 302, with the understanding that the processes described herein as being performed on the die 302 may also be performed (e.g., sequentially performed, simultaneously performed) on the remaining dies 302 of the wafer 300 prior to singulation.

FIG. 3B illustrates a cross section view of a die 302 from the wafer 300. A dielectric material layer (e.g., oxide) 304 is deposited on a non-active side 306 of the die resulting in the configuration in FIG. 3C. The dielectric layer 304 may be deposited via a process, such as but not limited to, a spin-on deposition process. An electrically conductive die attach film 308, which has a thickness, for example, of approximately 20-25 um, is deposited via lamination on the dielectric layer 304 resulting in a die assembly 310 illustrated in FIG. 3D. The die attach film 308 has adhesive properties on both sides, which facilitates attachment of the die attach film 308 to the dielectric layer 304.

As mentioned above, FIGS. 3E-3H illustrate the assembly process associated with the process of placing the die 302 on a substrate or leadframe and a molding process to thereby fabricate the electronic device 100 illustrated in FIGS. 1A and 1B. In the following description, the substrate is comprised of a leadframe. It is to be understood that in alternative examples, the substrate may be comprised of a laminate substrate or a printed circuit board based substrate. For illustrative purposes only, a leadframe based substrate will be described herein and illustrated in the drawings.

FIG. 3E illustrates a cross section view of a leadframe 312 that includes a die pad 314, inner leads 316, and outer leads 318. After the die assembly 310 is singulated from the wafer 300, the die assembly 310 is rotated 180° and is picked and placed onto the die pad 314 resulting in the configuration in FIG. 3F. The die attach film 308, which as mentioned above has an adhesive on both sides, secures the die assembly 310 to the die pad 314. Referring to FIG. 3G, one end of a critical signal wire bond 320 is attached to an active side 322 of the die 302 via a bond 324 formed by a bonding process (e.g., thermosonic bonding). An opposite end of the critical signal wire bond 320 is attached to the die pad 314 of the leadframe 312. Still referring to FIG. 3G, additional wire bonds 326 are attached to the active side 322 of the die 302 via the bond 324 formed by the bonding process (e.g., thermosonic bonding). Opposite ends of the wire bonds 326 are attached to the inner leads 316.

A molding compound 328 is formed over and encapsulates the die assembly 310, the die pad 314, the inner leads 316, the critical signal wire bond 320, and the wire bonds 326 resulting in the configured electronic device 330 in FIG. 3H. The outer leads 318 are not encapsulated by the molding compound 328. Although, not illustrated in the figures, the outer leads can be formed, shaped, or bent in a direction toward or away from the die 302, which would result in a leaded dual in-line IC package. Alternatively, the electronic device can be a non-leaded IC package, such as but not limited to a QFN, QFP, BGA packages.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

1. An electronic device comprising:
a leadframe having a die pad and leads;
a die attached to the die pad, the die including an active side, the die further including a dielectric layer deposited on a side of the die opposite that of the active side and a die attach film deposited on the dielectric layer; and
a wire bond attached from the active side of the die to the die pad;
a mold compound encapsulating the die, the wire bond, and a portion of the leadframe,
wherein a stacked formation of the die, the dielectric layer, and the die attach film form a capacitor that filters noise from a signal carried by the wire bond.

2. The electronic device of claim 1, wherein the die includes an electrically grounded and conductive substrate on the side opposite the active side that forms one electrically conductive plate of the capacitor.

3. The electronic device of claim 2, wherein the die attach film is an electrically conductive film that along with the die pad forms another electrically conductive plate of the capacitor.

4. The electronic device of claim 1, wherein the dielectric layer is comprised of an oxide and is deposited on the side opposite the active side of the die via a spin coating process.

5. The electronic device of claim 1, wherein the signal is one of a reference voltage and an output signal.

6. A method comprising:
attaching a die attach film on a non-active side of a die;
attaching the non-active side of the die to a die pad of a leadframe;
attaching a wire bond from an active side of the die to the die pad, wherein the active side is opposite of the non-active side; and
forming a molding compound over the die, the wire bond, and a portion of the leadframe,
wherein the formation of the die, the die attach film, and the die pad form a capacitor that filters noise from a signal from the die to the die pad via the wire bond.

7. The method of claim 6, wherein the die attach film is formed from a dielectric material that forms a dielectric layer of the capacitor.

8. The method of claim 7, wherein the die includes an electrically grounded and conductive substrate on the non-active side that forms one electrically conductive plate of the capacitor, and wherein the die pad forms another electrically conductive plate of the capacitor.

9. The method of claim 6, wherein prior to attaching a die attach film on the non-active side of the die, the method further including depositing a dielectric layer on the non-active side of the die.

10. The method of claim 9, wherein the dielectric layer is comprised of an oxide and is deposited on the non-active side of the die via a spin coating process.

11. The method of claim 10, wherein the die includes an electrically grounded and conductive substrate on the non-active side that forms one electrically conductive plate of the capacitor.

12. The method of claim 11, wherein the die attach film is an electrically conductive film that along with the die pad forms another electrically conductive plate of the capacitor.

13. The method of claim 9, wherein the leads are comprised of inner leads and outer leads, and wherein the molding compound is formed over the die pad and the inner leads, but is not formed over outer leads.

14. The method of claim 9, wherein the molding compound is formed over all but one surface of the leadframe, the one surface facing away from the die.

15. The method of claim 9, wherein the signal is one of a reference voltage and an output signal.

16. An electronic device comprising:
a leadframe having a die pad and leads;
a die attached to the die pad, the die including an active side and a non-active side opposite that of the active side;
a die attach film attached to the non-active side of the die that facilitates attachment of the die to the die pad;
a wire bond attached from the active side of the die to the die pad;
a mold compound encapsulating the die, the wire bond, and a portion of the leadframe,
wherein a stacked formation of the die, the die attach film, and the die pad form a capacitor that filters noise from a signal carried by the wire bond.

17. The electronic device of claim 16, wherein the die attach film is made from a dielectric material that forms a dielectric layer of the capacitor.

18. The electronic device of claim 17, wherein the die includes an electrically grounded and conductive substrate on the non-active side that forms one electrically conductive plate of the capacitor.

19. The electronic device of claim 18, wherein the die pad forms another electrically conductive plate of the capacitor.

20. The electronic device of claim 16, wherein the signal is one of a reference voltage and an output signal.
